(19) United States
(12) Patent Application Publication
(10) Pub. No.: US 2002/0098421 A1
(43) Pub. Date: Jul. 25, 2002

(54) Fabrication method of semiconductor integrated circuit device and mask fabrication method

(76) Inventors: Norio Hasegawa, Hinode (JP); Toshihiko Tanaka, Tokyo (JP); Tsuneo Terasawa, Ome (JP); Aritoshi Sugimoto, Tokyo (JP)

Correspondence Address: ANTONELLI TERRY STOUT AND KRAUS, SUITE 1800, 1300 NORTH SEVENTEENTH STREET, ARLINGTON, VA, 22209

(21) Appl. No.: 09/968,920

(22) Filed: Oct. 3, 2001

(30) Foreign Application Priority Data
Oct. 17, 2000 (JP) 2000-316965

(51) Int. Cl. G03F 9/00; H01L 21/302; H01L 21/461

(52) U.S. Cl. 430/5; 438/708; 438/736

(57) ABSTRACT

An area for fabricating a photomask having light-shielding patterns each formed of an organic film, and areas for fabricating a semiconductor integrated circuit device are provided within the same clean room. A manufacturing device and an inspecting device are commonly used upon the fabrication of the photomask and the fabrication of the semiconductor integrated circuit device.

### BACKGROUND OF THE INVENTION

The present invention relates to a method of fabricating a semiconductor integrated circuit device and a technology for fabricating a photomask, and particularly to a technology effective for application to a photolithography (hereinafter called simply “lithography”) technology for transferring predetermined patterns to a semiconductor wafer (hereinafter called simply “wafer”) according to exposure processing using a photomask (hereinafter called simply “mask”).

A lithography technology has been used in the fabrication of a semiconductor integrated circuit device as a method of transferring minute or micro patterns to a wafer. A projection exposure apparatus or system is principally used in the lithography technology, and patterns on a mask mounted to the projection exposure system are transferred to a wafer to thereby form device patterns.

A general mask used in such a projection exposing method has a structure wherein light-shielding patterns each formed of a metal film like chromium or the like are provided on a mask substrate transparent to exposure light. For instance, the following is known as a fabrication process thereof. First of all, a metal film made up of chromium or the like, which serves as a light-shielding film, is deposited on a transparent mask substrate, and a resist film photosensitive to an electron beam is applied onto the metal film. Subsequently, the electron beam is applied to predetermined points or locations of the resist film by an electron beam writing system or the like, followed by development of the resist film, whereby resist patterns are formed. Thereafter, the lower metal film is etched with the resist patterns as etching masks to thereby form light-shielding patterns each formed of the metal film. The finally-left resist film photosensitive to the electron beam is removed to fabricate a mask.

However, the mask having such a configuration is accompanied by a problem that the number of manufacturing processes increases and the cost thereof rises, and a problem that since the light-shielding patterns are processed by isotropic etching, the accuracy of processed dimensions is reduced. As a technology having taken into consideration such problems, for example, Unexamined Patent Publication No. Hei 5(1993)-289307 discloses a technology wherein light-shielding patterns on a mask substrate are made up of a resist film by using the fact that a predetermined resist film is capable of setting transmittance to 0% with respect to ArF excimer laser.

### SUMMARY OF THE INVENTION

However, the present inventors have found that the mask technology with the resist film formed as the light-shielding patterns has following problems.

The first is a problem that no sufficient consideration has been made to the fabrication of a mask with efficiency and in a short period. Custom products such as an ASIC (Application Specific IC), etc. need the number of man hours and a period necessary for product development as the demand for high functions is made. On the other hand, however, since the existing products erode quickly and the life of each product is short, it has been desirable to develop products and shorten their fabrication periods. Accordingly, an important problem is how to fabricate the mask used for the fabrication of such products in a short time and with efficiency.

The second is a problem that no sufficient consideration has been made to a further reduction in the cost of a mask. In recent years, the cost of the mask has increasingly been on the rise in a semiconductor integrated circuit device. This results from the following reasons, for example. Namely, since a market scale is small in the field of a mask manufacturing device, unprofitable conditions will occur. Expenses taken for developing a writing device for forming patterns on a mask and an inspecting device for inspecting the patterns, and their running costs will be mammoth with scaling-down of each pattern formed on the mask and its high integration. Thus, the cost of the mask must unavoidably be increased to collect their expenses or the like. Further, there is a tendency to increase the total number of masks necessary to fabricate one semiconductor integrated circuit device with an improvement in the performance of the semiconductor integrated circuit device. Even from this point of view, an important problem is how to reduce the cost of each mask.

An object of the present invention is to provide a technology capable of shortening the period required to fabricate a mask.

Another object of the present invention is to provide a technology capable of shortening the period required to fabricate a semiconductor integrated circuit device.

A further object of the present invention is to provide a technology capable of reducing the cost of a mask.

A still further object of the present invention is to provide a technology capable of reducing the cost of a semiconductor integrated circuit device.

The above, other objects, and novel features of the present invention will become apparent from the description of the present specification and the accompanying drawings.

Summaries of typical ones of the inventions disclosed in the present application will be described in brief as follows:

The present invention aims to carry out the fabrication of a semiconductor integrated circuit device, and the fabrication of a photomask having light-shielding patterns each formed of an organic film within the same clean room.

The present invention aims to share the use of a manufacturing device upon the fabrication of a semiconductor integrated circuit device and the fabrication of a mask having light-shielding patterns each formed of an organic film.

The present invention aims to share the use of an inspecting device upon the fabrication of a semiconductor integrated circuit device and the fabrication of a mask having light-shielding patterns each formed of an organic film.

The present invention aims to share the use of a manufacturing device and an inspecting device upon the fabrication of a semiconductor integrated circuit device and the fabrication of a mask having light-shielding patterns each formed of an organic film.

The present invention includes a step for transferring at least one predetermined pattern to a first semiconductor wafer according to a first exposure process using the photomask having the light-shielding patterns each formed of the organic film, inspecting the predetermined pattern transferred to the first semiconductor wafer to thereby determine whether each pattern on the photomask having the light-shielding patterns each formed of the organic film is good or bad, and transferring at least one predetermined pattern to a second semiconductor wafer according to a second exposure process using the photomask having the light-shielding patterns each formed of the organic film, which photomask has passed the above inspection.

### BRIEF DESCRIPTION OF THE DRAWINGS

While the specification concludes with claims particularly pointing out and distinctly claiming the subject matter which is regarded as the invention, it is believed that the invention, the objects and features of the invention and further objects, features and advantages thereof will be better understood from the following description taken in connection with the accompanying drawings in which:

FIG. 1 is a view for describing one example of the structure of a clean room according to one embodiment of the present invention;

FIG. 2(a) is an overall plan view of one example of a photomask used within the clean room shown in FIG. 1, and FIG. 2(b) is a cross-sectional view taken along line X-X of FIG. 2(a);

FIG. 3(a) is an overall plan view of another example of the photomask used within the clean room shown in FIG. 1, and FIG. 3(b) is a cross-sectional view taken along line X-X of FIG. 3(a);

FIG. 4(a) is an overall plan view of a further example of the photomask used within the clean room shown in FIG. 1, and FIG. 4(b) is a cross-sectional view taken along line X-X of FIG. 4(a);

FIG. 5(a) is an overall plan view of a still further example of the photomask used within the clean room shown in FIG. 1, and FIG. 5(b) is a cross-sectional view taken along line X-X of FIG. 5(a);

FIGS. 6(a) through 6(c) are respectively fragmentary cross-sectional views of a mask substrate placed during a manufacturing process for describing one example of a method of manufacturing the photomask shown in FIG. 2;

FIG. 7 is a view for describing one example of a reduction projection exposure system installed in the clean room shown in FIG. 1;

FIG. 8 is an overall plan view of a semiconductor wafer subjected to processing in respective areas;

FIG. 9(a) is a fragmentary enlarged plan view of the semiconductor wafer shown in FIG. 8 subsequent to a lithography process, and FIG. 9(b) is a cross-sectional view taken along line X-X of FIG. 9(a);

FIG. 10(a) is a fragmentary enlarged plan view of the semiconductor wafer shown in FIG. 8 subsequent to an etching process, and FIG. 10(b) is a cross-sectional view taken along line X-X of FIG. 10(a);

FIG. 11 is a flow chart showing a fabrication process of a photomask and a fabrication process of a semiconductor integrated circuit device, both showing one embodiment of the present invention;

FIGS. 12(a) through 12(e) are respectively views for describing a method of inspecting a photomask, which shows one embodiment of the present invention;

FIG. 13 is a view for describing one example of an inspection apparatus used in an inspecting process of a photomask, showing one embodiment of the present invention; and

FIG. 14 is a view for describing operation modes of a clean room according to another embodiment of the present invention.

### DETAILED DESCRIPTION OF THE PREFERRED EMBODIMENTS

Prior to the detailed description of the invention of the present application, the meaning of terms employed in the present application will be explained as follows:

1. Mask (Optical Mask): A mask is one in which patterns for shielding light and patterns for changing the phase thereof are formed over a mask substrate. It includes a reticle formed with patterns each having a few times the actual size. A first principal or main surface of the mask means a pattern surface over which the patterns for shielding the light and the patterns for changing the phase thereof are formed. A second main surface thereof means a surface (i.e., reverse side or back) located on the opposite side of the first main surface.

2. Normal mask: A normal mask is a kind of the mask referred to above, and means a general or common mask in which mask patterns are formed over a mask substrate by using light-shielding patterns each formed of a metal and light-transmissive patterns.

3. Resist light-shielding mask: It is a kind of the mask referred to above, and means a mask having a light shielder (corresponding to each of the light-shielding film, light-shielding pattern and light-shielding region) formed of an organic film, which is formed on a mask substrate.

4. A pattern surface of a mask (corresponding to each of the normal mask and the resist light-shielding mask) is classified into the following areas or regions. They are a region “integrated circuit pattern region” in which each integrated circuit pattern to be transferred is laid out, and its outer peripheral region “peripheral region”.

5. The terms “light shielder”, “light-shielding region”, “light-shielding film” and “light-shielding pattern” described herein indicate that they have optical characteristics for causing ones of 40% or less, of exposure lights applied to their regions to pass therethrough. In general, ones of from a few % to 30% or less are used. On the other hand, the terms “transparent”, “transparent film”, “light transmissive region” and “light transmissive pattern” described herein indicate that they include optical characteristics for causing ones of 60% or more, of exposure lights applied to their regions to pass therethrough. In general, ones of 90% or more are used.

6. A wafer indicates a silicon monocrystal substrate (which is commonly substantially plane circular), a sapphire substrate, a glass substrate, another insulating, semi-insulating or semiconductor substrate, and a combined substrate thereof all of which are used in the manufacture of an integrated circuit. As semiconductor integrated circuit devices described in the present application, ones or the like formed over other insulating substrates such as glass like TFT (Thin-Film-Transistor) and STN (Super-Twisted Nematic) liquid crystals or the like will also be included as well as over a semiconductor or an insulator substrate such as a silicon wafer, a sapphire substrate or the like, except for a case specified as being not so in particular.

7. A wafer process indicates the process of starting from the state of a mirror polishing wafer (mirror wafer), forming a surface protective surface through a device and wiring forming process and finally allowing an electrical test to be executed by a probe.

8. A device surface is a main surface of a wafer and indicates a surface over which device patterns corresponding to a plurality of chip regions are formed by lithography.

9. Transfer pattern: It is a pattern transferred onto a wafer by a mask. Described specifically, it is called a pattern placed over the wafer, which is actually formed with the photoresist pattern and a photoresist pattern as masks.

10. Resist pattern: It is called a film pattern obtained by patterning a photosensitive resin film by a photolithography method. Incidentally, this pattern includes a mere resist film perfectly free of openings with respect to the corresponding portion.

11. Normal illumination: It is non-transformational illumination and means illumination relatively uniform in light intensity distribution.

12. Transformational illumination: It is illumination lowered in illumination intensity of a central portion, and includes multiple-polarity illumination such as oblique illumination, orbicular-zone illumination, quadruple-polarity illumination, quintuple-polarity illumination, or a ultra-resolution technique using a pupil filter equivalent to it.

13. Scanning exposure: It is an exposing method of relatively continuously moving (scanning) a thin slit-like exposure zone or band in a direction orthogonal to the longitudinal direction of a slit (it may be shifted obliquely) with respect to a wafer and a mask to thereby transfer circuit patterns placed over the mask to desired portions over the wafer. A device for executing the exposing method is called a scanner.

14. Step and scan exposure: It is a method of utilizing the scanning exposure and a stepping exposure in combination to thereby expose a portion to be exposed over a wafer over its entirety. This corresponds to the subordinate concept of the scanning exposure.

15. Step and repeat exposure: It is an exposing method of repeatedly stepping a wafer with respect to a projected image of each circuit pattern on a mask to thereby transfer the circuit pattern on the mask to a desired portion on the wafer. A device for executing the exposing method is called a stepper.

16. Chemical mechanical polish (CMP) means that in a state in which a surface to be ground or polished is being made contact with a polishing or scouring pad formed of a relatively soft cloth-like sheet material or the like, the surface is ground while being moved relative to a surface direction while slurry is being supplied thereto. In the present application, the chemical mechanical polish includes others, i.e., CML (Chemical Mechanical Lapping) for moving the surface to be polished relative to a hard grinding surface to thereby perform grinding, one using other fixed abrasive grains, and abrasive grains-free CMP unusing abrasive grains, etc.

Whenever circumstances require it for convenience in the following embodiments, they will be described by being divided into a plurality of sections or embodiments. However, unless otherwise specified in particular, they are not irrelevant to one another. One thereof has to do with modifications, details and supplementary explanations of some or all of the other.

When reference is made to the number of elements or the like (including the number of pieces, numerical values, quantity, range, etc.) in the following embodiments, the number thereof is not limited to a specific number and may be greater than or less than or equal to the specific number unless otherwise specified in particular and definitely limited to the specific number in principle..

It is needless to say that components (including element or factor steps, etc.) employed in the following embodiments are not always essential unless otherwise specified in particular and considered to be definitely essential in principle.

Similarly, when reference is made to the shapes, positional relations and the like of the components or the like in the following embodiments, they will include ones substantially analogous or similar to their shapes or the like unless otherwise specified in particular and considered not to be definitely so in principle, etc. This is similarly applied even to the above-described numerical values and range.

Those each having the same function in all the drawings for describing the embodiments are respectively identified by the same reference numerals and their repetitive description will therefore be omitted.

In the drawings employed in the present embodiments, matching is applied to light-shielding portions (light-shielding film, light-shielding patterns, light-shielding regions, etc. and resist films to make it easier to see the drawings even if they are plan views.

Preferred embodiments of the present invention will hereinafter be described in details with reference to the accompanying drawings.

### (EMBODIMENT 1)

In the present embodiment, a description will be made of a case in which mask fabrication and a wafer process are executed within the same clean room.

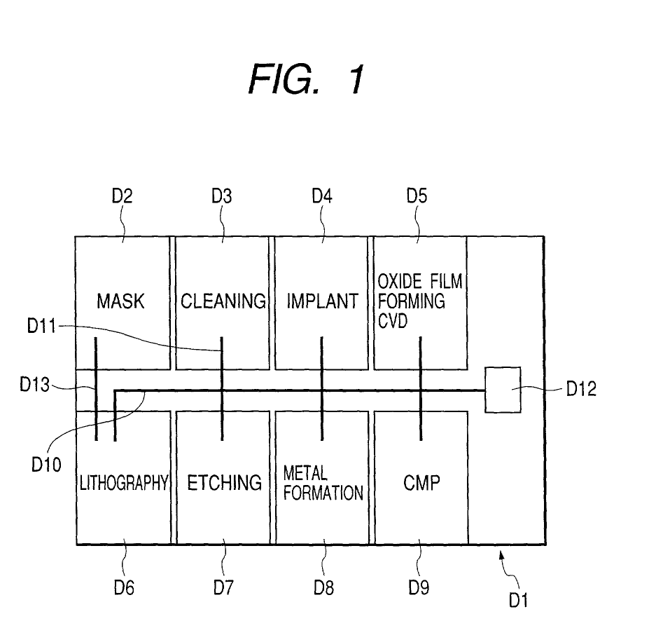

FIG. 1 shows one example of a structure or configuration of a clean room D1 showing one embodiment of the present invention. Both of a mask fabrication line area D2) and lines (areas D3 through D9) for fabricating a semiconductor integrated circuit device are accommodated in the clean room D1. The mask fabrication line and a wafer process line can share the use of facilities in some areas. Thus, the amount of capital investment can be reduced to about half as compared with the case where a manufacturing device and an inspecting or testing device are separately prepared for a process for fabricating a mask and a process for fabricating the semiconductor integrated circuit device. Since the manufacturing device and testing device used in the fabrication process of the semiconductor integrated circuit device can be used in the fabrication process of the mask, the efficiency of availability of such manufacturing and testing devices can be improved. Further, when the mask is delivered from the mask fabrication line to the fabrication line of the semiconductor integrated circuit device, the packaging of the mask can be made unnecessary because the mask is placed within the same clean room D1, and a transfer path for its delivery can also be shortened. It is therefore possible to cut or reduce the expense and time spent for the packaging and delivery. Thus, the cost of the mask can be reduced. It is therefore possible to reduce the cost of the semiconductor integrated circuit device.

Further, the transfer of information between the fabrication line of the mask and the fabrication line of the semiconductor integrated circuit device can be carried out through a dedicated or exclusive line like a LAN (Local Area Network) or the like, for example. Thus, information about the mask, like mask quality information or the like such as progress information about mask fabrication, position accuracy, dimensional accuracy, etc. can be offered or given from the fabrication line of the mask to the fabrication line of the semiconductor integrated circuit device in real time. On the contrary, the information can also be supplied from the fabrication line of the semiconductor integrated circuit device to the fabrication line of the mask. Since an external line like Internet or the like may not be used upon transmission and reception of the information, the amount of information transmittable and receivable for a predetermined time can be increased, and the leakage of secret and virus infection can be prevented from occurring. Thus, safety can also be ensured. Of course, the information can also be transferred therebetween by means of an information storage medium like an optical disk or the like.

The fabrication process (wafer process) of the semiconductor integrated circuit device runs to a few hundred of process steps. As principal ones, however, the fabrication process can be classified into, for example, a lithography step, an etching step, a step for growing or depositing an oxide film or the like, an ion injection step, a metal forming step, a polishing step such as CMP or the like, a cleaning step, etc. The areas D3 through D9 for executing these steps are simply separated from one another and functionally placed so that respective processes are efficiently carried out in a divided state.

The area D3 is an area for cleaning the wafer and mask by means of a cleaning device. The area D4 is an area for introducing a predetermined impurity into the wafer by an ion implanter. The area D5 is an area for growing a predetermined insulating film on the wafer by, for example, an oxidation method or a CVD (Chemical Vapor Deposition) method. The area D6 is lithography for transferring a predetermined pattern to the wafer by using the mask or the like fabricated in the area D2. For example, any one of an exposure apparatus or system with an F₂ excimer laser (whose wavelength is 157 nm) as a light source of exposure, an exposure system with an ArF excimer laser (whose wavelength is 248 nm) as a light source of exposure, and an exposure system with an i ray (whose wavelength =365 nm) as a light source of exposure, or preferably, the selected two or three thereof, or all thereof can be disposed in the area D6 as an illustrative example. Since exposure corresponding to a demand can be performed owing to the placement of the plural exposure systems different in exposure condition in this way, a semiconductor integrated circuit device high in performance can be fabricated with efficiency. Further, a device for performing development, cleaning and the like subsequent to exposure processing is also placed in the area D6. The area D7 is an area for effecting etching processing on the wafer. The area D8 is an area for depositing a metal film on the wafer. The area D9 is an area for effecting polishing processing on the wafer.

Such a clean room D1 is provided with a mechanism for providing line automation from the viewpoint of a reduction in or prevention of the occurrence of foreign materials, etc. The respective areas D2 through D9 are coupled to one another through carrier or transfer lines. A transfer line D10 disposed in the center or the clean room D1 is a main transfer line for conveying or transferring a wafer and a mask and is mechanically connected to the areas D3 through D9 via transfer lines D10 which branch off from the main transfer line. A wafer carrying-in/carrying-out port D12 is mechanically connected to ends of the transfer lines D10. A plurality of sheets of wafers to be processed from now on are held or accommodated in the wafer carrying-in/carrying-out port D12 and thereafter automatically conveyed to the respective areas D3 through D9 via the transfer lines D10 one by one. On the other hand, the processed wafers are automatically fed to the wafer carrying-in/carrying-out port D12 through the transfer lines D10 one by one again. The area D6 for the lithography and the area D2 for the mask fabrication are mechanically connected to each other through a mask transfer line D13.

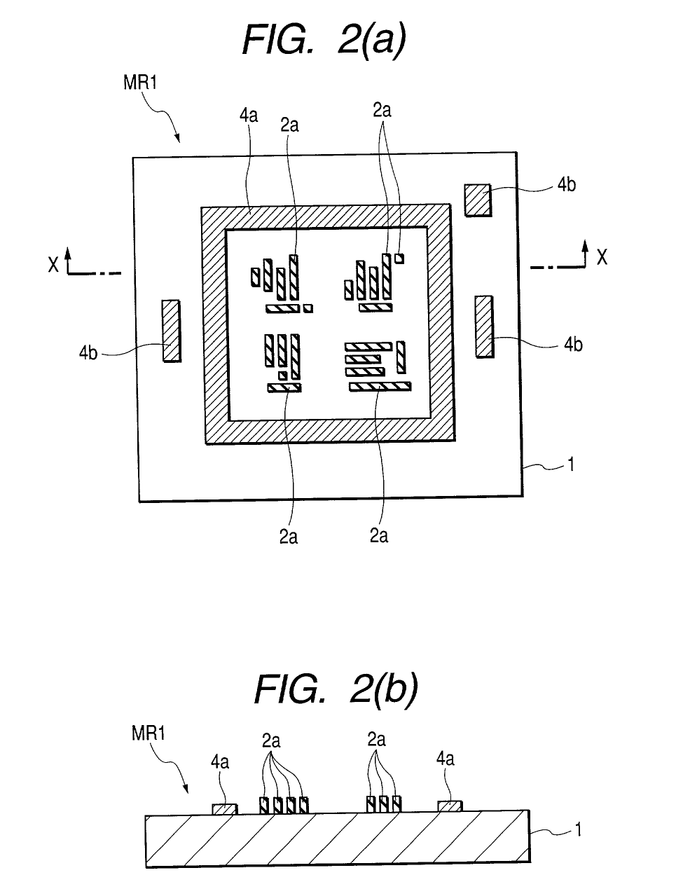

Examples of structures of resist light-shielding masks used in the present embodiment will next be described. FIGS. 2 through 5 respectively show examples of the resist light-shielding masks MR1 through MR4. FIGS. 2(a) through 5(a) are respectively overall plan views of the resist light-shielding masks MR1 through MR4, and FIGS. 2(b) through 5(b) are respectively cross-sectional views take along lines X-X of FIGS. 2(a) through 5(a).

Each of the resist light-shielding masks MR1 through MR4 is a reticle for focusing or image-forming an original of an integrated circuit pattern having a size equal to, for example, 1 to 10 times the actual or exact size onto a wafer through a reduction projection optical system or the like and thereby transferring it. Each of mask substrates 1 of the resist light-shielding masks MR1 through MR4 shown in FIGS. 2 through 5 is formed of a transparent composite quartz substrate having a thickness of about 6 mm, which is shaped in the form of a plane quadrangle, for example. The integrated circuit pattern region is disposed in the center of a first main surface of each mask substrate 1, and its outer periphery serves as the peripheral region. A mask pattern for transferring an integrated circuit pattern is formed in the integrated circuit pattern region. Although not restricted in particular, the resist light-shielding masks MR1 through MR4, any of which is used to transfer each wiring pattern or the like, are illustrated by way of example herein. The present embodiment illustrates as an example, a case in which wring patterns identical in shape are transferred even if any of the resist light-shielding masks MR1 through MR4 is used.

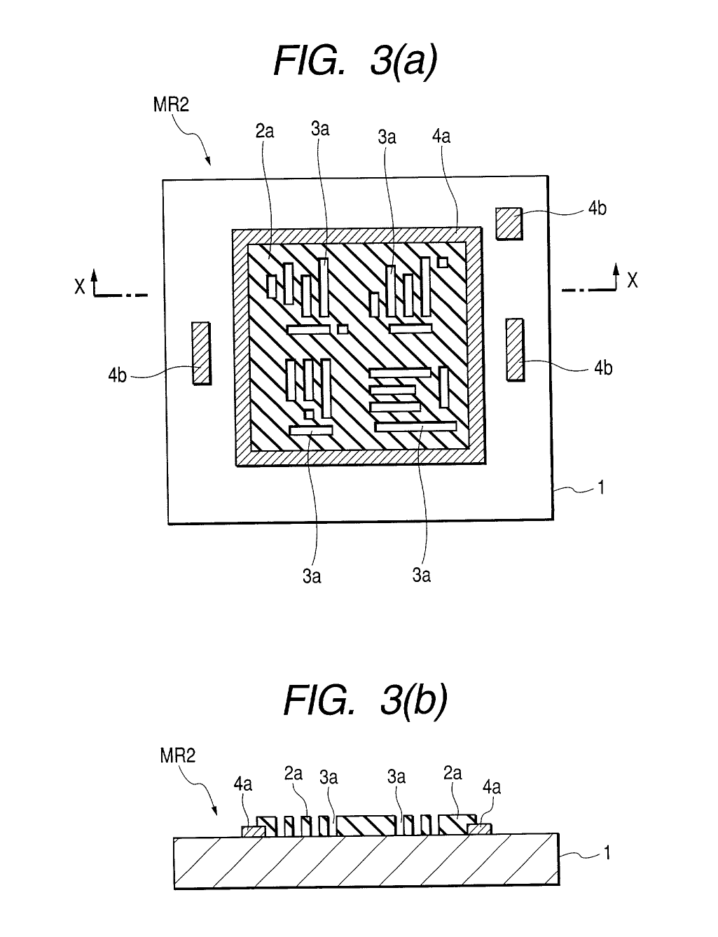

The resist light-shielding masks MR1 and MR2 shown in FIGS. 2 and 3 illustrate or exemplify mask structures in which light-shielding patterns 2a in integrated circuit pattern regions are all formed of an organic film. In FIG. 2, the light-shielding patterns 2a are transferred onto a wafer as the wiring patterns. In FIG. 3, light-transmissive patterns 3a exposed from their corresponding light-shielding patterns 2a are transferred onto a wafer as the wiring patterns. In the resist light-shielding masks MR1 and MR2, light-shielding patterns 4a each formed of a metal film are respectively formed so as to surround the outer peripheries of the integrated circuit pattern regions. Further, light-shielding patterns 4b each formed of a metal film are formed outside the light-shielding patterns 4a. The light-shielding patterns 4b are capable of exemplifying alignment marks or the like used upon alignment of the mask with its corresponding exposure system or wafer. Thus, since the detection capability of each alignment mark can be ensured as usual even if an exposure system for detecting the position of the mask by means of a halogen lamp or the like is used, the alignment accuracy of a mask equivalent to the normal mask can be ensured. Since the light-shielding patterns each made up of the organic film are not provided in peripheral regions or areas in the resist light-shielding masks MR1 and MR2, it is possible to prevent the occurrence of foreign materials due to abrasion of the light-shielding patterns each formed of the organic film and their losses.

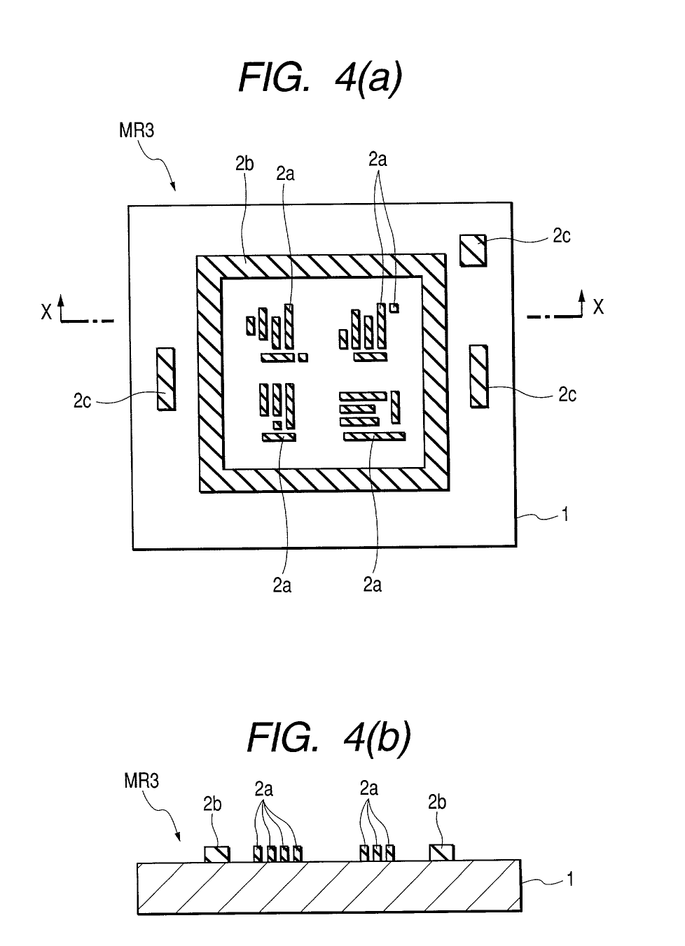

The mask MR3 shown in FIG. 4 exemplifies a mask structure in which light-shielding patterns 2a through 2c in an integrated circuit pattern region and its peripheral region are all formed of an organic film. The light-shielding patterns 2b and 2c are respectively patterns identical in shape and function although different in material from the light-shielding patterns 4a and 4b. Since the light-shielding patterns 2a through 2c are all formed of the organic film and there is not provided a metal film etching process step in the case of the mask MR3, the time required to fabricate the mask MR3 can be shortened as compared with other resist light-shielding masks MR1, MR2 and MR4, and the manufacturing cost thereof can be reduced.

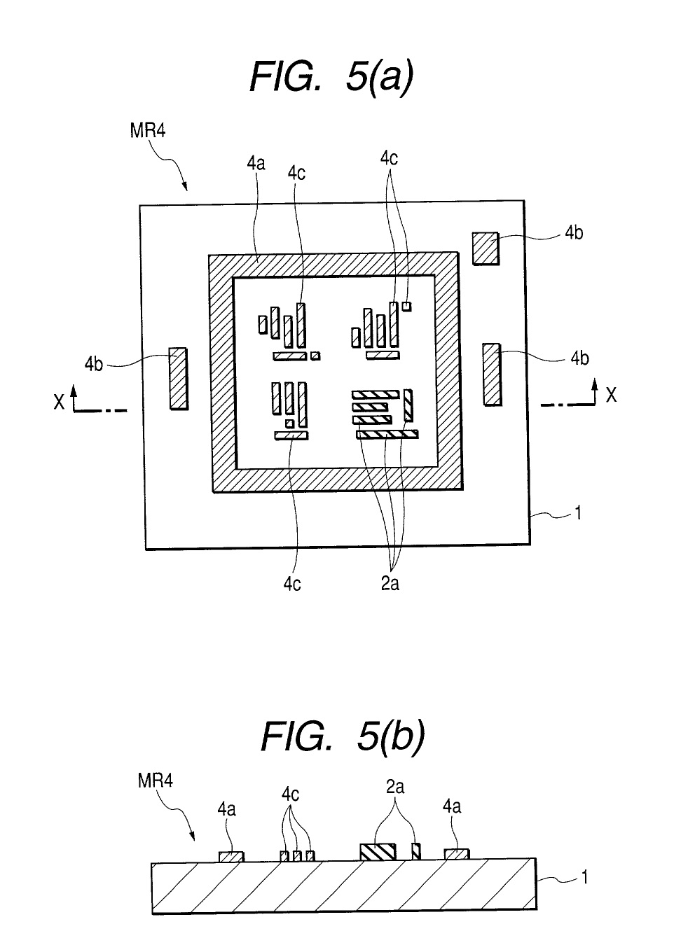

The mask MR4 shown in FIG. 5 exemplifies a mask structure wherein both light-shielding patterns 2a each formed of an organic film and light-shielding patterns 4c each formed of a metal film are disposed in an integrated circuit pattern region. In this case, it is possible to carry out partial modifications (modifications to the light-shielding patterns 2a formed of the organic film) to mask patterns in the integrated circuit pattern region. A peripheral region is identical in configuration to the resist light-shielding masks MR1 and MR2 shown in FIGS. 2 and 3, and an effect equivalent to the above is obtained.

In the case of any of the resist light-shielding masks MR1 through MR4, the formation and removal of the light-shielding patterns 2a can easily be carried out as compared with the normal mask owing to the formation of the light-shielding patterns 2a lying in the integrated circuit pattern region with the organic film. It is therefore possible to drastically shorten the time required to fabricate each of the resist light-shielding masks MR1 through MR4 and greatly reduce its manufacturing cost. Since no etching is carried out upon formation of the light-shielding patterns 2a , pattern dimensional errors produced due to the etching can be avoided and correspondingly, the dimensional accuracy of each transferred pattern can be improved.

As an organic material for the light-shielding patterns 2a through 2c, may be exemplified, a photosensitive resin (resist) film. The resist film for forming the light-shielding patterns 2a through 2c has the property of absorbing exposure light such as a KrF excimer laser light (wavelength: 248 nm), an ArF excimer laser light (wavelength: 193 nm) or an F² laser light (wavelength: 157 nm) or the like. Further, the resist film has a light-shielding function approximately similar to the light-shielding patterns formed of the metal. As the resist film for forming each of the light-shielding patterns 2a through 2c, was used, for example, one with copolymer of α-methylstyrene and α-chloroacrylic acid, a novolak resin and quinone diazide, a novolak resin and polymethylpenten-1-sulfone, chloromethylated polystyrene, etc. as principal components. A so-called chemical-amplification type resist or the like obtained by mixing a phenol resin like a polyvinyl phenol resin or the like or a novolak resin with inhibitor and an acidogenic agent can be used. The material for the light-shielding resist film used herein may have a light-shielding characteristic with respect to a light source of a projection exposure system or aligner and a characteristic having sensitivity to a light source of a pattern drawing or writing apparatus in a mask fabrication process, e.g., electron beams or light having wavelength of 230 nm or more. No limitation is imposed on the material and the material can be changed in various ways.

When a polyphenol and novolak resin is formed with a thickness of about 100 nm, the transmittance thereof is substantially zero at wavelengths ranging from about 150 nm to about 230 nm, for example, and it has a mask effect sufficient for an ArF excimer laser light having a wavelength of 193 nm, an F² laser having a wavelength of 157 nm, etc., for example. Although the present example is intended for the vacuum ultraviolet light having the wavelength of 200 nm or less, it is not limited to it. Exposure light having a wavelength longer than 200 nm as in the case of the KrF excimer laser light (wavelength: 248 nm), the i ray (whose wavelength is 365 nm), etc. can be used. In such a case, it is necessary to use other resist materials or add an absorbing material or a light-shielding material to the resist film. The technology of forming each light-shielding pattern by the resist film has been described in Unexamined Patent Application No. Hei 11(1999)-185221 (filed on Jun. 30, 1999), Unexamined Patent Application No. 2000-206728 (filed on Jul. 7, 2000) and Unexamined Patent Application No. 2000-206729 (filed on Jul. 7, 2000).

Further, each of the light-shielding patterns 3a through 3c formed of the metal film comprises a metal film like chromium or the like, for example. However, the material for each of the light-shielding patterns 3a through 3c is not limited to it and can be changed in various ways. As the material, may be used, for example, a high melting point metal like tungsten, molybdenum, tantalum or titanium or the like, nitride like tungsten nitride, high melting point silicide (compound) like tungsten silicide (WSix), molybdenum silicide (MoSix) or the like, or a film formed by stacking these on one another. In the case of each of the resist light-shielding masks MR1 through MR4 according to the present embodiment, the mask substrate 1 might be cleaned and used again after the light-shielding patterns 2a through 2c formed of the organic film have been removed. Therefore, the high melting point metal like tungsten or the like excellent or rich in oxidation resistance, abrasion resistance and peeling resistance is preferable as the material for the light-shielding patterns 3a through 3c.

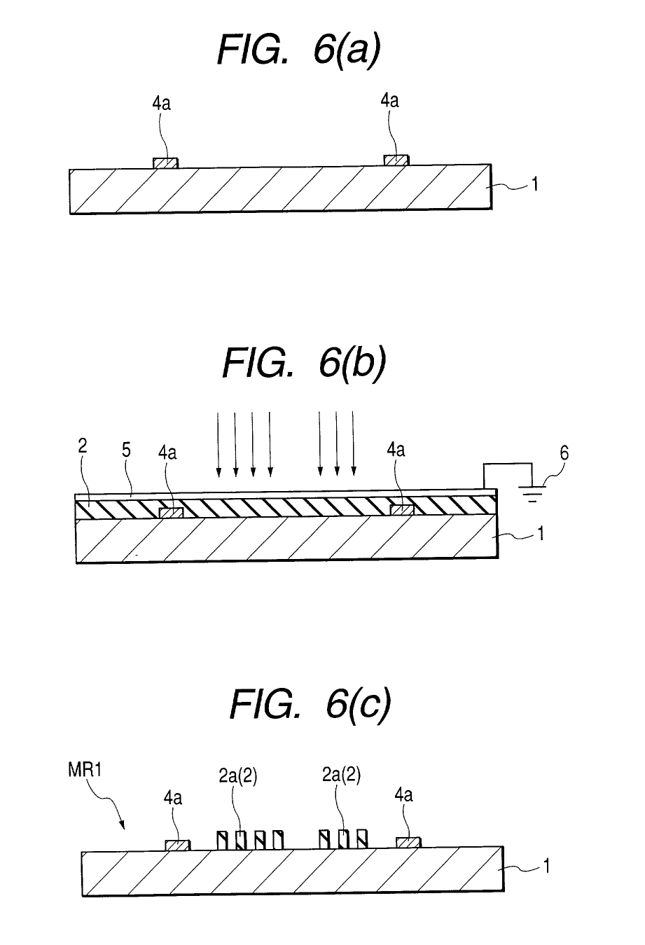

One example of a method of fabricating a mask, according to the present embodiment will next be described. A method of fabricating the resist light-shielding mask MR1 will be explained as one example herein. As shown in FIG. 6(a), a mask substrate 1 (i.e., a mask blank. Incidentally, the mask substrate per se unformed with the light-shielding patterns made up of the metal is used as each of mask blanks in the mask MR3 of FIG. 4.) already formed with light-shielding patterns 4a and 4b formed of a metal film is first prepared. As shown in FIG. 6(b), a resist film 2 for forming the light-shielding patterns 2a through 2c is applied to a first main surface of the mask substrate 1. Subsequently, an antistatic water-soluble conductive organic film 5 is applied onto the resist film 2. As the water-soluble conductive organic film 5, was used, for example, Espacer (manufactured by Showa Denko K.K.), Aquasave (manufactured by Mitsubishi Rayon Co., Ltd.) or the like. Afterwards, an electron beam drawing or writing process for pattern writing was done in a state in which the water-soluble conductive organic film 5 and the earth 6 are electrically connected to each other. Thereafter, the water-soluble conductive organic film 5 was also removed upon development processing of the resist film 2. A resist light-shielding mask MR1 having the light-shielding patterns 2a formed of the resist film 2 in an integrated circuit pattern region is fabricated as shown in FIG. 6(c) in the above-described manner.

Incidentally, the pattern writing for the resist film is not limited to electron beam writing. The writing of each pattern, etc. through the use of an ultraviolet ray of 230 nm or more, for example, can be applied. A so-called resist film hardening process is also effective wherein after such light-shielding patterns 2a through 2c formed of the resist film 2 have been formed, they are subjected to heat treatment or powerfully irradiated with an ultraviolet ray to improve the resistance to the radiation of exposure light. The holding of each pattern surface in an inert gas atmosphere of nitrogen (N²) or the like is also effective with the objective of preventing the oxidization of the light-shielding resist film 2.

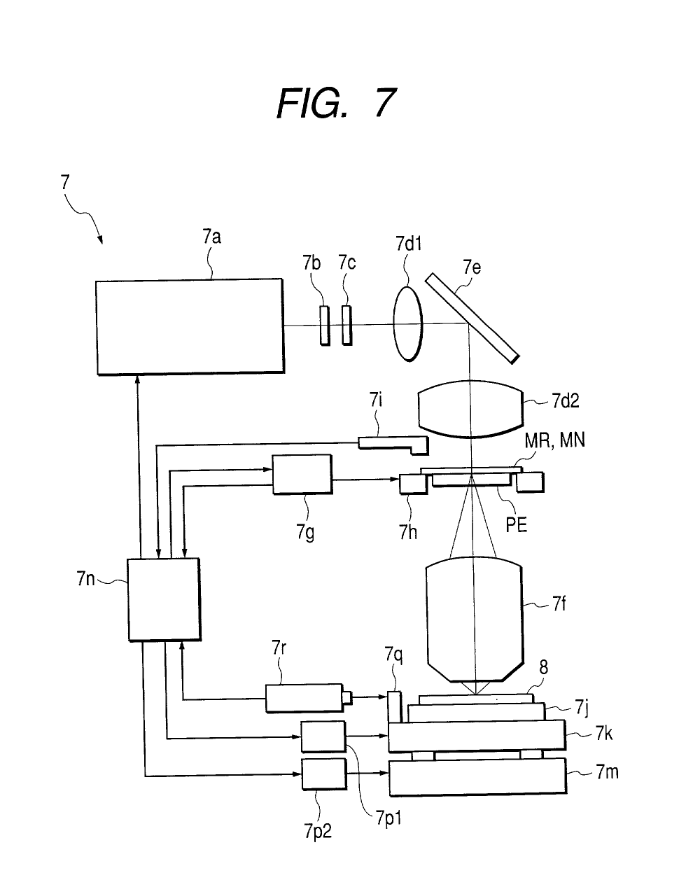

One example of a reduction projection exposure system used in the above exposure processing is shown in FIG. 7. Exposure light emitted from a light source 7a of a reduction projection exposure system 7 is applied to either the resist light-shielding mask MR exemplified by each of the resist light-shielding masks MR1 through MR4 or the normal mask MN, which is placed on a mask stage, via a flyeye lens 7b, an illumination-shape adjustment aperture 7c, condenser lenses 7d1 and 7d2, and a mirror 7e. For example, the KrF, ArF excimer laser, F² laser light or i ray or the like is used as an exposure light source as described above. The resist light-shielding mask MR or the normal mask MN is placed on the reduction projection exposure system 7 in a state in which a first main surface thereof formed with light-shielding patterns is directed downward (to the wafer 8 side). Accordingly, the exposure light is applied from the second main surface side of the resist light-shielding mask MR or the normal mask MN. Thus, a mask pattern drawn or written over the resist light-shielding mask MR or the normal mask MN is projected onto a device surface of a wafer 8 corresponding to a sample substrate through a projection lens 7f. The pellicle PE is provided over the first main surface of the resist light-shielding mask MR or the normal mask MN as the case may be. Incidentally, the resist light-shielding mask MR or the normal mask MN is vacuum-absorbed at a mounting portion of a mask stage 7h controlled by mask position control means 7g and aligned by position detecting means 7i. Thus, the alignment between its center and an optical axis of the projection lens 7f is done accurately.

The wafer 8 is absorbed onto a sample table 7j under vacuum in a state in which the device surface thereof is directed upward. The sample table 7j is placed over a Z stage 7k movable in the direction of the optical axis of the projection lens 7f, i.e., in a Z-axis direction and further placed over an XY stage 7m. Since the Z stage 7k and the XY stage 7m are driven by their corresponding drive means 7p1 and 7p2 according to control commands delivered from a main control system 7n, each of both stages can be shifted to a desired exposure position. The position is accurately monitored by a laser length-measuring device 7r as a position for a mirror 7q fixed to the Z stage 7k. Further, for example, a normal halogen lamp is used as the position detecting means 7i. Namely, it is not necessary to use a specific light source for the position detecting means 7i (newly introduce a new technology and a difficult technology). The previously-known reduction projection exposure system can be used. The main control system 7n is electrically connected to a network apparatus and is capable of performing remote supervision or the like of the state of the reduction projection exposure system 7. As the exposing method, may be used, for example, either the step and repeat exposing method or scanning exposing method (step and scanning exposing method) . As the exposure light source, the normal illumination may be used or the transformational illumination may be used.

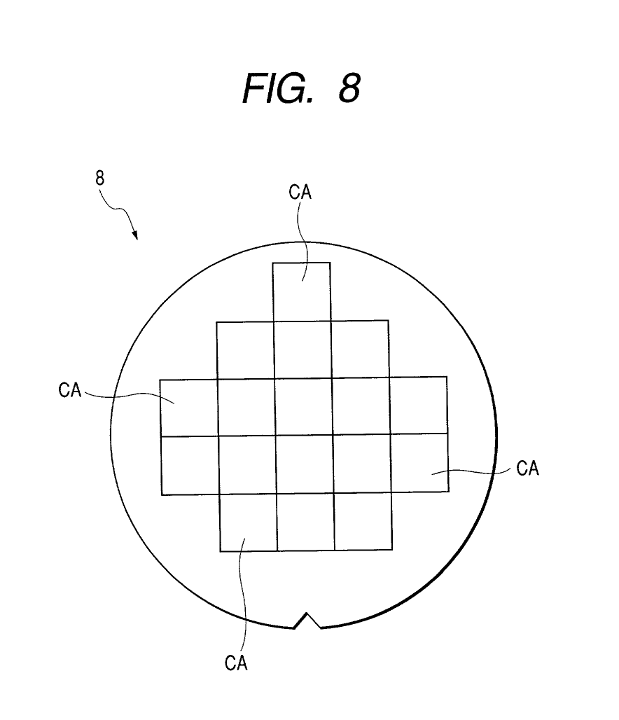

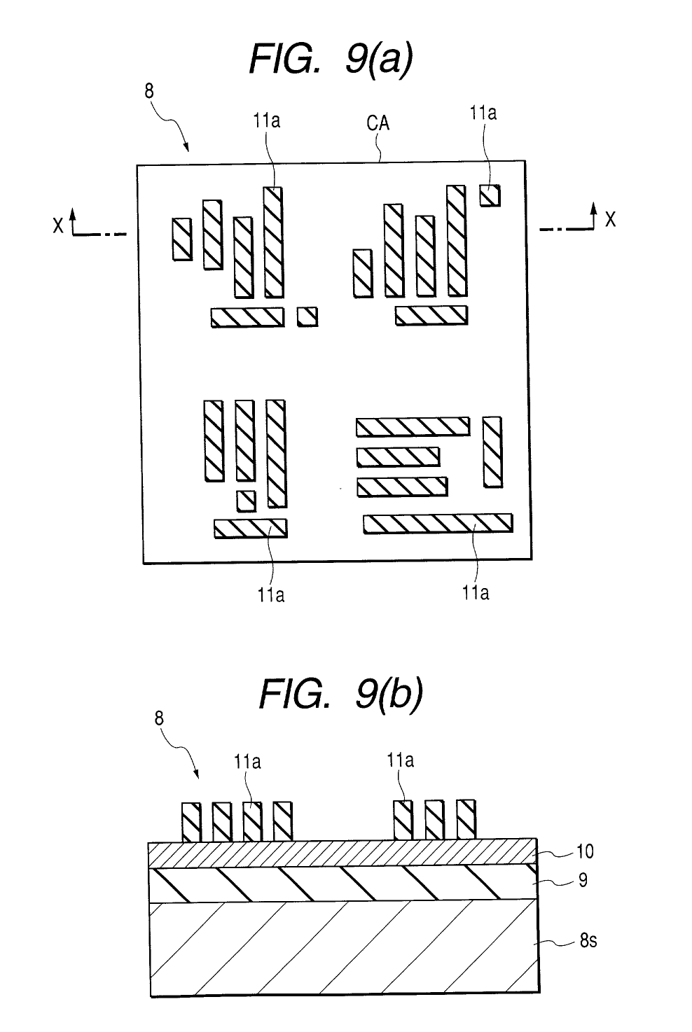

FIG. 8 is an overall plan view of a wafer 8 subjected to exposure processing by the reduction projection exposure system 7 through the use of any of the resist light-shielding masks MR1 through MR4. The wafer 8 is shaped in plan circular form, for example. For instance, a plurality of chip areas CA each shaped in the form of a square are regularly placed side by side on a main surface of the wafer 8. FIG. 9(a) is an enlarged plan view of the chip area CA shown in FIG. 8, and FIG. 9(b) is a cross-sectional view taken along line X-X of FIG. 9(a). A semiconductor substrate 8S, which constitutes the wafer 8, comprises, for example, a silicon monocrystal. A conductive or conductor film 10 formed of, for example, aluminum or tungsten or the like is deposited over a device surface of the semiconductor substrate 8S with an insulating film 9 formed of, for example, silicon oxide interposed therebetween. The conductor film 10 is deposited in the metal forming area D8 shown in FIG. 1 by a sputtering method or the like. Further, normal resist patterns 11a each having a thickness of about 300 nm, each of which has photosensitivity to ArF, for example, are formed on the conductor film 10. Incidentally, when the resist light-shielding masks MR1, MR3 and MR4 are used, the resist patterns 11a make use of positive-type ones, whereas when the resist light-shielding mask MR2 is used, they make use of negative-type ones, respectively.

Upon the exposure processing of such resist patterns 11a, a reduction projection exposure system 7 with, for example, an ArF excimer laser light having a wavelength of 193 nm as a light source of exposure was used. For example, 0.68 was used as an numerical aperture NA of a projection lens, and for example, 0.7 was used as coherency σ of a light source. The alignment between the reduction projection exposure system 7 and the resist light-shielding mask MR was done by detecting each metal film-made light-shielding pattern 4c of the resist light-shielding mask MR. A helium-neon (He-Ne) laser light having a wavelength of 633 nm, for example, was used for the alignment herein. Since the contrast of light is sufficiently obtained in this case, the relative alignment between the resist light-shielding mask MR and the exposure system could be done with ease and high accuracy.

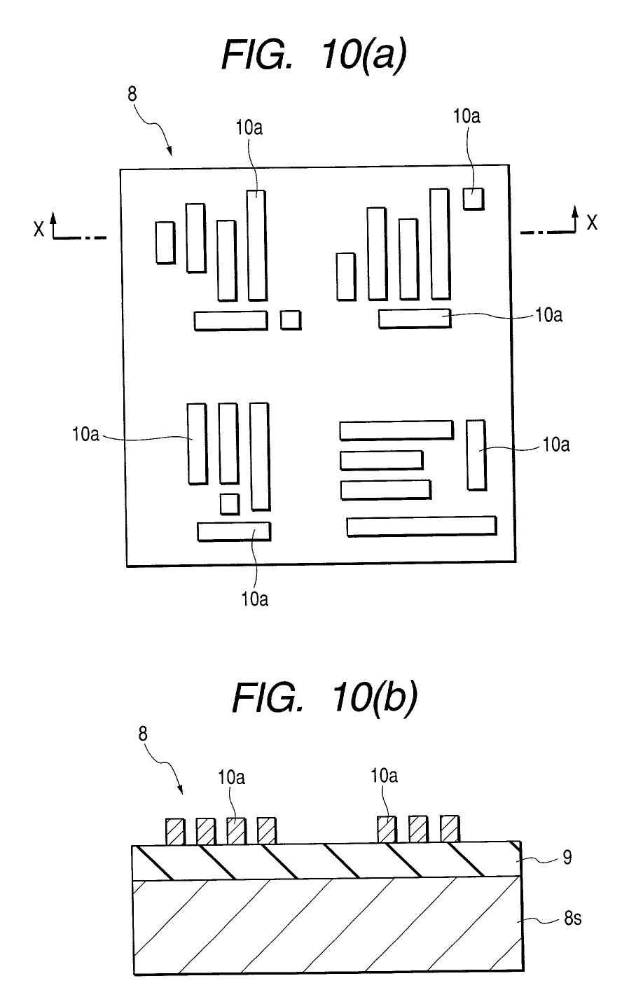

FIG. 10(a) is a fragmentary enlarged plan view of the wafer 8 in the chip area CA, which has been conveyed to the etching area D7 shown in FIG. 1 and subjected to etching processing, and FIG. 10(b) is a cross-sectional view taken along line X-X of FIG. 10(a). Wiring patterns 10a each formed of the conductor film 10 are formed on an insulating film 9. A pattern transfer characteristic approximately identical to that obtained upon exposure using the normal mask was obtained herein. For example, a 0.19-μm line and space could be formed at a focal depth of 0.4 μm.

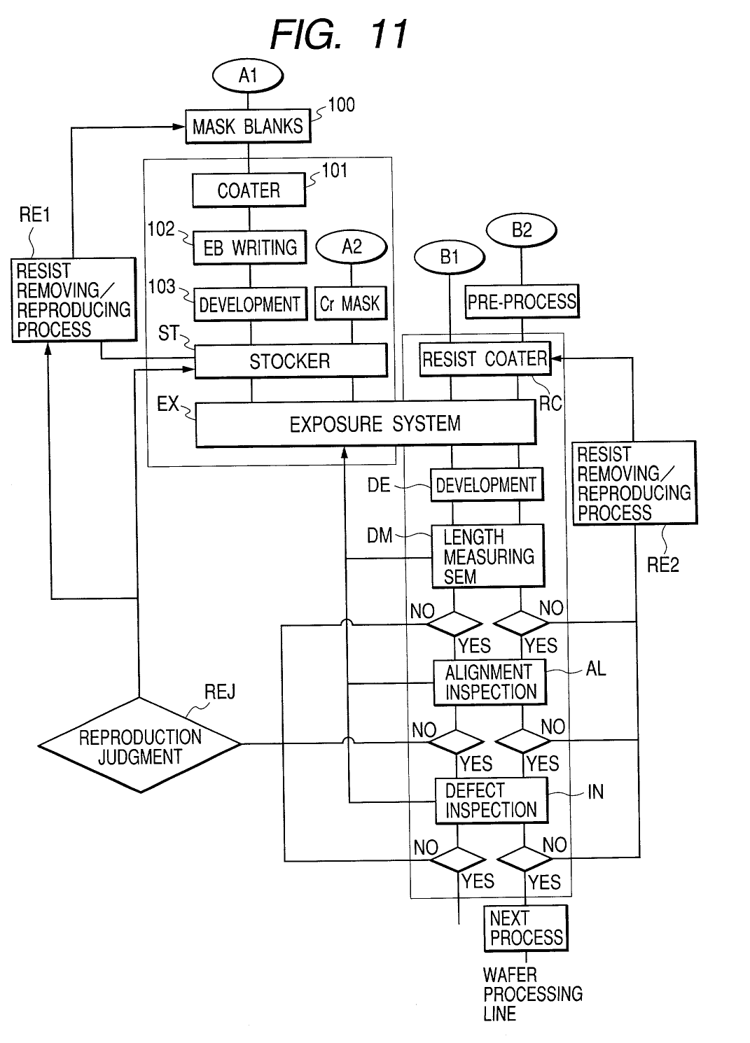

Next, actual flows for the fabrication process of the mask and the fabrication process of the semiconductor integrated circuit device, which are used in the present embodiment, are shown in FIG. 11.

A flow A1 indicates the flow for the fabrication process of the resist light-shielding mask MR. Namely, the flow A1 proceeds in order of a step 100 for preparing each of the mask blanks, a step 101 for applying a light-shielding pattern forming resist film and a conductive film onto a first main surface of the mask blank as described above, a step 102 for transferring an integrated circuit pattern to the resist film by an electron beam writing process or the like as described above, a step 103 for carrying out a developing process and a cleaning process, and a step ST for holding or accommodating the resist light-shielding mask MR already subjected to the developing process in a stocker.

In the present embodiment, the exposure system (illustrated in FIG. 7 by way of example) used in the fabrication process (wafer process) of the semiconductor integrated circuit device is used to transfer a pattern for a resist light-shielding mask MR to be tested or inspected to a wafer (first wafer) for inspection (first exposure process) and inspect or test the transferred pattern, thereby determining whether the pattern for the resist light-shielding mask MR to be inspected is good or bad. Inspecting the transferred pattern on the wafer in this way to thereby inspect the pattern for the mask allows substantial inspection of the pattern. It is therefore possible to improve the reliability of mask inspection. Since it is possible to improve the reliability of the mask inspection, the re-inspection of the mask or the like can be lessened. It is therefore possible to achieve an improvement in the efficiency of manufacture of the mask, the shortening of a development period thereof and the shortening of a fabrication period thereof. Accordingly, a development period of the semiconductor integrated circuit device and a manufacturing period thereof can be shortened. It is further possible to improve mask's yields. Also the expense spent for the re-inspection of the mask can be reduced or cut down. Owing to these, the cost of the mask can be reduced. Accordingly, the cost of the semiconductor integrated circuit device can be reduced.

A flow B1 indicates the flow of processing for the wafer for the inspection. Namely, a resist film is first applied onto a device surface of the wafer for inspection (resist applying step RC). Subsequently, the resist light-shielding mask MR to be inspected is mounted to the exposure system used in the fabrication process of the semiconductor integrated circuit device to effect exposure processing on the wafer for inspection (Step EX). Thereafter, a developing process is effected on the wafer for inspection (Step DE).

Next, the flow B1 proceeds to a step for inspecting each transferred pattern formed on the wafer for inspection. In the present step, various devices are used to check for the shape of the transferred pattern on the wafer for inspection and check for the quality of the resist light-shielding mask MR to be inspected. A short size (corresponding to the transversely-extending size of the transferred pattern) of the transferred pattern, and a long size (corresponding to the longitudinally-extending size of the pattern) are respectively determined or measured by relative comparison with a reference pattern on the wafer for inspection by use of a length measuring SEM (Scanning Electron Microscope) and an optical alignment inspecting device, for example (Steps DM and AL). A defect inspection is carried out by, for example, a visual inspecting SEM or an optical pattern shape comparing/inspecting device (Step IN).

Inspection results are respectively processed based on the determination of pass or rejection. Namely, when the determination of the rejection is made, the resist light-shielding mask MR to be inspected is delivered to a resist removal reproduction processing step RE1 according to a reproduction judgment (Step REJ) . A mask substrate 1 subsequent to the removal of the resist is reused as each of mask blanks. On the other hand, when the determination of the pass is reached, inspected data is fed back to a correction input unit of the exposure system and thereby used for improvements in transfer accuracy at actual fabrication of a semiconductor integrated circuit device. For example, the amount of light exposure of the exposure system is corrected based on the results of size measurements, or the alignment correction value of the exposure system is corrected based on the result of alignment inspection.

The exposure system used for the inspection of the mask and the exposure system used for the transfer of each device pattern (integrate circuit pattern) are used as the same one in this way in the present embodiment. Thus, since, for example, various errors, lens aberration, etc. inherent to the exposure systems are the same, information obtained in the inspection step can effectively be utilized as exposure conditions for the transfer of each device pattern. Therefore, since the exposure conditions for each device pattern can be set to better ones, various accuracies such as the dimensional accuracy of each device pattern, the alignment accuracy thereof, etc. can be improved. Thus, it is possible to improve the yield and reliability of the semiconductor integrated circuit device.

Further, a flow A2 indicates the flow of a normal mask. The normal mask fabricated in a step other than in the present embodiment is directly stored in the mask stocker (Step ST). Since the normal mask has already been inspected, the inspections employed in the present embodiment are unnecessary.

On the other hand, a flow B2 indicates the flow of processing for a wafer (second wafer) for each device, which is formed with a semiconductor integrated circuit device. The wafer is delivered from a pre-process and enters the resist applying step RC. The wafer passes through the exposure processing step (second exposure processing) EX using the mask having passed the mask inspecting step and the development processing step DE and flows into the respective inspecting steps DM, AL and IN. Inspection results are respectively processed based on the judgment of pass or rejection. When the judgment on the rejection is made, a resist light-shielding mask to be inspected is delivered to a resist removal reproduction processing step RE2 according to a reproduction judgment. Regardless of the pass or rejection, the inspection results are fed back to a correction file (correction coefficient or the like) of the exposure system one by one, and fed back to the next lot or the same type of next lot. Incidentally, the feedback of the inspection results is normally not carried out directly. The inspection results pass through a statistics analytical process of data and are thereafter fed back to the exposure system in a state of being converted into correction data.

According to the present embodiment as described above, QTAT (Quick Turn Around Time) for the fabrication of the mask can be realized, and the mask and the semiconductor integrated circuit device can be manufactured efficiently. Therefore, this can cope even with the fabrication of each product that desires a short delivery period as in the case of ASIC or the like. Also this can cope even with such products or periods that the development period and inspection period or the like of ASIC, a mask ROM (Read Only Memory), or a semiconductor integrated circuit device, the shape and size or the like of each pattern are unstable and their changes are frequently performed, in a short time and at low cost as compared with the case in which only the normal mask is used with respect thereto.

A description will next be made of a pattern defect inspection for the resist light-shielding mask MR or the normal mask.

As a method of inspecting defects and shapes of general patterns on a mask may be mentioned, for example, a database comparing inspection and a die-to-die inspection. The database comparing inspection is a method of, when laser light for inspection is directly applied to a mask to be inspected or tested, comparing a pattern image obtained by detecting light reflected from the mask or light transmitted through the mask or detecting the two with mask design data to thereby determine whether each pattern on the mask is good. This is also a method of forming the same circuit patterns in a plurality of different areas (chip areas CA) lying within a mask and comparing the same circuit patterns lying in the different areas with one another to thereby determine or judge whether each pattern on the mask is good.

However, the method of inspecting each pattern on the mask may cause a case in which when small or micro patterns (patterns or the like of a resolution limit or less) exist in the mask, inspection is unfeasible and detection errors occur. In particular, there have recently been increasing tendencies to apply an optical proximity correction (OPC) or a phase shift technology to a lithography technology to thereby place patterns each having a resolution limit or less on a mask in a lithography process step or place specific patterns on the mask. The above-described problem becomes pronounced. In the present embodiment, as a method of solving such a problem, the database comparing inspection or the die-to-die inspection is effected on patters actually transferred to the wafer by the exposure processing using the masks (resist light-shielding mask and normal mask) to be inspected as described above. It is thus possible to substantially inspect whether each pattern having a shape and a size that meet demands, is actually formed on the wafer. A capital investment can be cut down owing to the use of the inspecting device used in the fabrication process of the semiconductor integrated circuit device as described above.

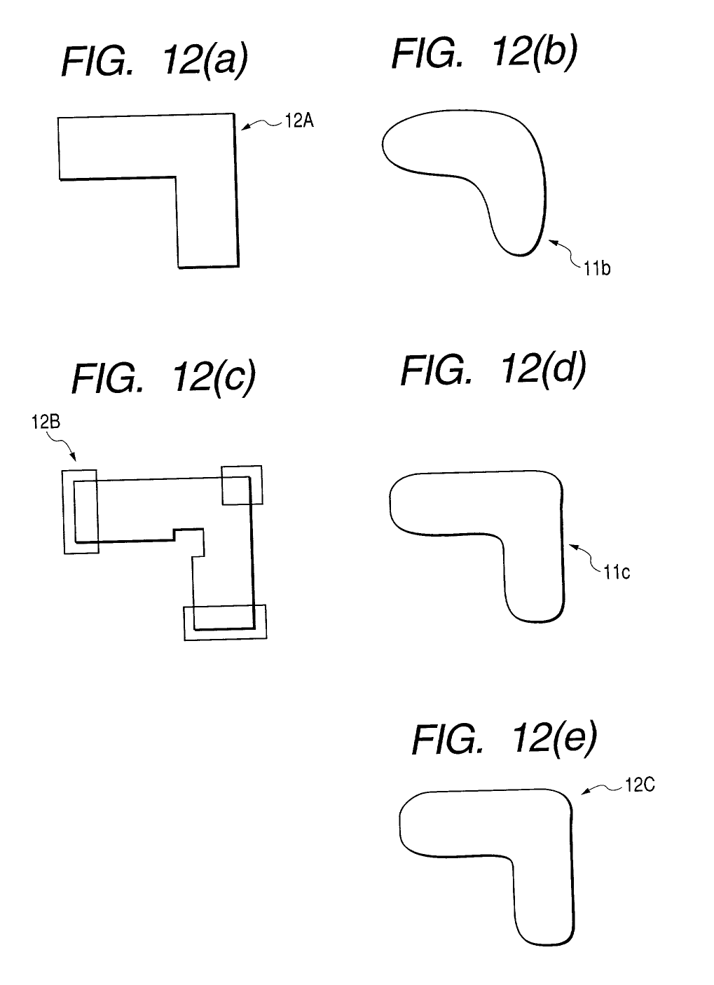

A specific one example of a defect inspection of each mask pattern employed in the present embodiment will now be described with reference to FIG. 12.

FIG. 12(a) shows one example of pattern data 12A of an OPC-free mask. This is a pattern for design data about an integrated circuit pattern and shows the shape of a pattern that is desirous of being transferred to a resist film on a wafer. FIG. 12(b) shows a plane or planar shape of a resist pattern 11b at the time that exposure processing is done by using the mask shown in FIG. 12(a). The shape of the resist pattern 11b is deformed into a shape quite alien to the pattern shape shown in FIG. 12(a). Therefore, OPC is effected on the pattern data 12a shown in FIG. 12(a) to thereby create pattern data 12B shown in FIG. 12(c). FIG. 12(d) shows a planar shape of a resist pattern 11c at the time that exposure processing is done by use of the mask shown in FIG. 12(c). The shape thereof is coincident in side positions with the shape of the pattern shown in FIG. 12 (a). If the pattern shown in FIG. 12(a) is rounded at the corners thereof, then the pattern shown in FIG. 12(a) results in a shape substantially coincident with that shown in FIG. 12(d). Further, the pattern shape shown in FIG. 12(d) can be predicted even by pattern data 12C shown in FIG. 12(e) obtained by simulating a projected image using mask data shown in FIG. 12(c).

Thus, in the present embodiment, a visual inspecting SEM was used to thereby effect a database comparing inspection on the shape of the mask pattern 12A shown in FIG. 12(a) and the shape of the resist pattern 11c of FIG. 12(d) transferred onto a wafer through the use of the mask shown in FIG. 12(c). As a result, an error in size at OPC, an error in size of the mask could be detected. Even when the pattern data 12C (see FIG. 12(e)) obtained by simulating the shape of the transferred pattern using the mask of FIG. 12(c) is used as a database, defects and shape irregularities can be detected similarly.

Such an inspection can be applied even to a case in each which phase shift patterns exist in a mask. When it is desired to determine whether the phase shift patterns are good, such a determination is performed by making a comparison between actual pattern data and its corresponding transferred pattern or between a simulation pattern and its corresponding transferred pattern in a manner similar to the above. When it is desired to determine whether the phase of each phase shift pattern is good, a focal point is shifted or the amount of light exposure is changed upon exposure processing using a mask to be inspected. When a dimensional difference occurs in the transferred pattern at this time, the phase of the phase shift pattern can be judged to present a problem. No pattern is resolved when there is no phase shift pattern at the place where it exists originally, even if the focal point and the amount of light exposure remain unchanged. Therefore, a decision as to whether the layout or placement of each phase shift pattern is proper, can be made from the above viewpoint.

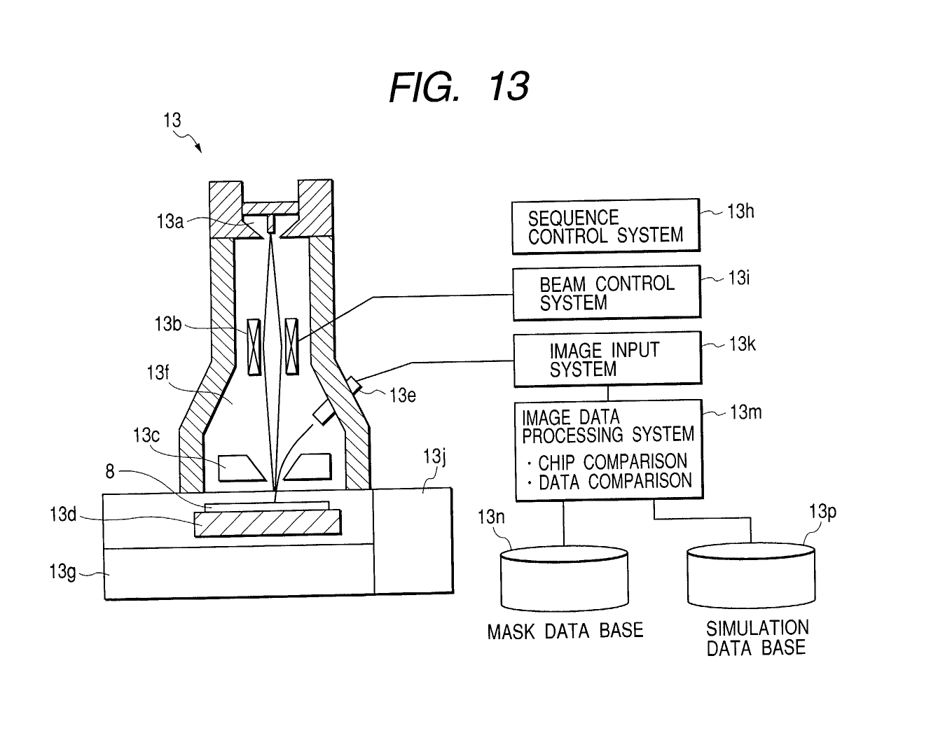

One example of a configuration of the visual inspecting SEM used in the inspecting step is shown in FIG. 13. A visual inspecting SEM 13 is capable of detecting a secondary electron or the like discharged from an electron-beam scan surface of a wafer 8 by means of a detection unit 13e when an electron beam EB emitted from an electron gun 13a is caused to scan on a device surface of the wafer 8 on a stage 13d through a beam deflection system 13b and an objective lens 13c or the like, thereby obtaining an image on the electron-beam scan surface. Upon electron beam scanning, a processing chamber 13f is held thereinside in a vacuum state by means of a vacuum control system 13g. The operation of the visual inspecting SEM 13 is controlled by a sequence control system 13h. Beam control of the beam deflection system 13b is carried out by a beam control system 13i. Incidentally, the carrying in and out of the wafer 8 are performed through a loader system 13j.

A secondary electron signal detected by the detection unit 13e is transmitted to an image input system 13k, where it is converted into image data. The image data is transmitted to an image data processing system 13m, where a chip comparing inspection and a data comparing inspection are performed. In the present embodiment, there are provided a mask data base 13n, and a simulation data base 13p. Design data about each pattern for a mask is stored in the mask data base 13n. Pattern data having predicted the above-described shape of transferred pattern is stored in the simulation data base 13p. These data are referred to as reference data (data to be compared) upon the comparison inspection by the image data processing system 13m.

### (EMBODIMENT 2)

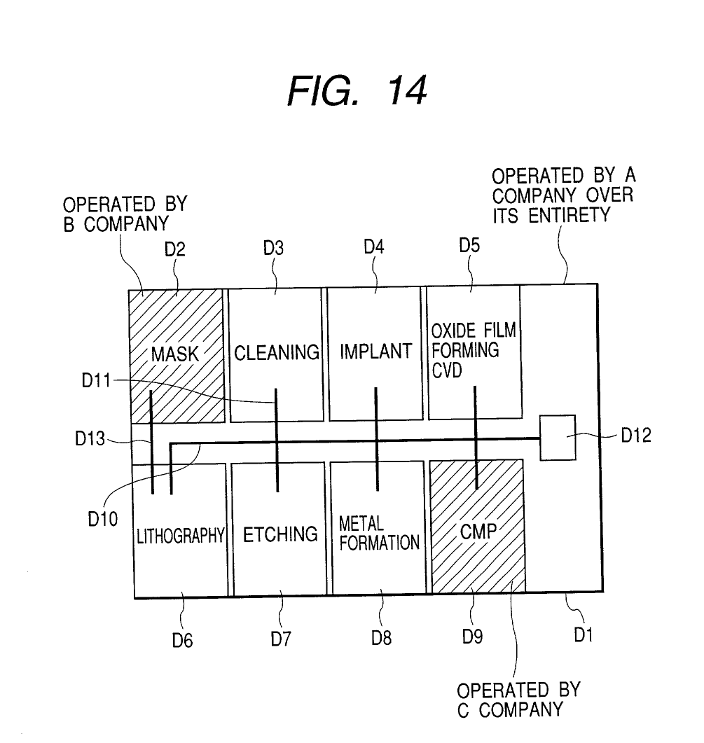

In the present embodiment, a description will be made of a modification illustrative of the operation modes of the clean room with reference to FIG. 14. Since the clean room D1 shown in FIG. 14 is identical in structure to that shown in FIG. 1, the description thereof will therefore be omitted.

A company A that is a manufacturer of a semiconductor integrated circuit device, for example, performs the whole management and operation of the clean room D1. The company A have maintenance and jurisdiction over physical facilities of the whole clean room D1 and takes legal procedures about property management, for example. The present embodiment exemplifies cases in which a company B that is a mask manufacturer, operates a mask fabrication area D2, and a company C operates an area D9 for CMP.

The company A provides locations or sites and basic fuels such as electricity, running water, etc. for the companies B and C. As an alternative to the company A, the companies B and C respectively prepare facilities and materials necessary for their own work, such as manufacturing devices and materials necessary for their fabrication, etc. The company A is capable of cutting down a capital investment. On the other hand, the companies B and C can reduce their amounts of investment because there is no need to ensure the locations. As described in the embodiment 1, the company B is capable of achieving an improvement in the efficiency of fabrication of a mask, an improvement in the reliability thereof and a reduction in cost thereof.

The company A regularly pays a predetermined amount of operational funds for the companies B and C according to a cuttable capital investment. The operational funds are an amount obtained by causing each of the companies B and C to subtract a rental rate to be paid for the company A therefrom. The company A pays a few percentages of sales of products fabricated by contribution thereto by the companies B and C to the companies B and C. If, for example, the company B corresponding to the mask manufacturer is selected in this case, then the amount to be accepted changes depending on the yield of each mask and the number of fabricated masks. For example, the more the yield increases, the more the receivable amount increases. If the number of fabricated masks good in quality increases, then a receivable amount also increases. Of course, the companies B and C are also capable of manufacturing ones other than the products fabricated by the company A.

Even in the case of the present embodiment, the fabrication of the mask and semiconductor integrated circuit device is identical to that in the embodiment 1. For instance, the fabrication thereof is as follows:

First of all, the company B corresponding to the mask manufacturer fabricates the resist light-shielding mask within the area D2 in the clean room D1. Further, a normal mask is prepared. Subsequently, the company B delivers the fabricated resist light-shielding mask and the prepared normal mask to the company A corresponding to the manufacturer of the semiconductor integrated circuit device. Namely, the company B transfers the resist light-shielding mask and the normal mask to the area D6.

The company A effects exposure processing on a wafer in a state in which the resist light-shielding mask and the normal mask are set to a reduction projection exposure system installed in the area D6 to thereby transfer each pattern to the wafer, and inspects the transferred pattern as described in the embodiment 1. As a result, a check is made as to whether the patterns for the delivered resist light-shielding mask and the normal mask are good or bad.

Regardless of whether the resist light-shielding mask and the normal mask are good or bad, the company A provides information obtained in the mask inspecting step for the company B corresponding to the mask manufacturer through the exclusive line such as the LAN or the like or the information storage medium such as the optical disk. When the resist light-shielding mask or the normal mask has passed as a result of the mask inspection, the company A transfers an integrated circuit pattern to the wafer according to exposure processing using the mask and the reduction projection exposure system in the area D6. At this time, the company A adjusts (corrects) exposure conditions of the exposure system according to the information obtained in the mask inspecting step. Subsequently, the company A proceeds to the normal fabrication process of the semiconductor integrated circuit device through steps similar to the embodiment 1. On the other hand, when the mask is found to be rejected as the result of the mask inspection, the company A returns the mask to the company B corresponding to the mask manufacturer. Namely, the company A conveys the same to the area D2.

The company B having received the rejected mask removes light-shielding patterns formed of an organic film from a mask substrate when the mask corresponds to the resist light-shielding mask, and brings the mask substrate into a state of being re-available as each of mask blanks. Further, the company B fabricates a new resist light-shielding mask or a new normal mask while taking into consideration the information obtained as the result of the inspecting step, and delivers it to the company A again.

While the invention made above by the present inventors has been described specifically by the illustrated embodiments, the present invention is not limited to the embodiments. It is needless to say that various changes can be made thereto within the scope not departing from the substance thereof.

When, for example, the patterns like the alignment marks or the like for the mask are formed of the resist film in the above-describe embodiment, an absorbent material for absorbing mark detection light (e.g., probe light (corresponding to light having a wavelength longer than an exposure wavelength, e.g. wavelength of 500 nm: information detection light) for a defect inspecting device) may be added to the resist film.

Further, while the embodiment has described the case in which the electron beam is used to transfer the patterns on the mask substrate, the present invention is not limited to it. Various changes can be made thereto. For example, a laser beam may be used.

While the above description has principally been made of the case in which the invention made by the present inventors is applied to the fabrication method of the semiconductor integrated circuit device which belongs to the field of application corresponding to the background of the invention, the present invention is not limited to it. The present invention can be applied even to, for example, a method of fabricating a disk which needs to transfer a predetermined pattern according to exposure processing using a mask, a method of fabricating a liquid crystal display, or a method of fabricating a micromachine.

Advantageous effects obtained by typical ones of the inventions disclosed by the present application will be descried in brief as follows:

(1) According to the present invention, the fabrication of a semiconductor integrated circuit device, and the fabrication of a photomask having light-shielding patterns each formed of an organic film are carried out within the same clean room, thereby making it possible to shorten the period required to fabricate the mask.

(2) According to the above (1), since the mask fabrication period can be shortened, the period required to fabricate the semiconductor integrated circuit device can be shortened.

(3) According to the present invention, the fabrication of a semiconductor integrated circuit device and the fabrication of a photomask having light-shielding patterns each formed of an organic film are performed within the same clean room, thereby making it possible to reduce the cost of the mask.

(4) According to the above (4), the semiconductor integrated circuit device can be reduced in cost.

What is claimed is:

1. A method of fabricating a semiconductor integrated circuit device, comprising the step of:
fabricating a photomask having light-shielding patterns each formed of an organic film within the same clean room used for fabrication lines of the semiconductor integrated circuit device.

2. The method according to claim 1, wherein a predetermined semiconductor integrated circuit device is fabricated by using a plurality of exposure systems different in exposure conditions, which are provided in a photolithography area used in the fabrication lines of the semiconductor integrated circuit device.

3. The method according to claim 1, further comprising the steps of:
(a) transferring a predetermined pattern to a first semiconductor wafer according to a first exposure process using the photomask having the light-shielding patterns each formed of the organic film;
(b) inspecting said predetermined pattern transferred to the first semiconductor wafer to thereby determine whether each pattern on the photomask having the light-shielding patterns each formed of the organic film is good or bad; and
(c) transferring a predetermined pattern to a second semiconductor wafer according to a second exposure process using the photomask having the light-shielding patterns each formed of the organic film, said photomask having passed in said inspecting step.

4. The method according to claim 3, wherein the first and second exposure processes make use of the same exposure system used in the fabrication lines of the semiconductor integrated circuit device.

5. The method according to claim 3, wherein said inspecting step has a step for inspecting a size and a defect of said predetermined pattern transferred to the first semiconductor wafer to thereby determine whether each pattern on the photomask is good or bad.

6. The method according to claim 3, wherein said inspecting step includes a step for measuring a long size of said predetermined pattern transferred to the first semiconductor wafer to thereby determine whether each pattern on the photomask is good or bad.

7. The method according to claim 3, wherein said inspecting step includes a step for measuring a short size of said predetermined pattern transferred to the first semiconductor wafer to thereby determine whether each pattern on the photomask is good or bad.

8. The method according to claim 3, wherein said inspecting step includes a step for inspecting long and short sizes of said predetermined pattern transferred to the first semiconductor wafer to thereby determine whether each pattern on the photomask having the light-shielding patterns each formed of the organic film is good or bad.

9. The method according to claim 3, wherein information obtained in said inspecting step is used as information at the second exposure process.

10. A method of fabricating a semiconductor integrated circuit device, comprising the steps of:
(a) fabricating a photomask by a photomask manufacturing company;
(b) delivering the photomask fabricated by the photomask manufacturing company to a company for manufacturing the semiconductor integrated circuit device;
(c) causing the semiconductor integrated circuit device manufacturing company to inspect a pattern transferred according to a first exposure process using the photomask to thereby determine whether each pattern on the photomask is good or bad;
(d) causing the semiconductor integrated circuit device manufacturing company to provide the photomask manufacturing company with information obtained in said inspecting step; and
(e) causing the semiconductor integrated circuit device manufacturing company to transfer an integrated circuit pattern to a semiconductor wafer according to a second exposure process using the photomask having passed in said inspecting step.

11. The method according to claim 10, wherein upon the second exposure process, the semiconductor integrated circuit device manufacturing company adjusts exposure conditions for an exposure system, based on the information obtained by the photomask inspecting step.

12. The method according to claim 10, wherein the step for fabricating the photomask by the photomask manufacturing company and the step for inspecting the photomask by the semiconductor integrated circuit device manufacturing company are executed within the same clean room.

13. The method according to claim 10, wherein the photomask has light-shielding patterns each formed of an organic film.

14. The method according to claim 10, wherein the photomask comprises two types of a first photomask having light-shielding patterns each formed of an organic film, and a second photomask having only light-shielding patterns each formed of a metal film.

15. A method of fabricating a photomask, comprising the steps of:
(a) transferring a predetermined pattern to a semiconductor wafer according to an exposure process using the photomask; and
(b) inspecting the predetermined photomask transferred to the semiconductor wafer to thereby determine whether each pattern on the photomask is good or bad.

16. The method according to claim 15, wherein said inspecting step includes a step for measuring a long size of said predetermined pattern transferred to the semiconductor wafer to thereby determine whether each pattern on the photomask is good or bad.

17. The method according to claim 16, wherein the measurement of the long size is carried out by measuring the amount of a displacement relative to any of marks formed on the semiconductor wafer.

18. The method according to claim 17, wherein the long size is measured by an optical alignment inspecting device.

19. The method according to claim 15, wherein said inspecting step includes a step for measuring a short size of said predetermined pattern transferred to the semiconductor wafer to thereby determine whether each pattern on the photomask is good or bad.

20. The method according to claim 19, wherein the short size is measured by a length measuring scanning electron microscope.

21. The method according to claim 15, wherein said inspecting step includes a step for inspecting long and short sizes of said predetermined pattern transferred to the semiconductor wafer to thereby determine whether each pattern on the photomask is good or bad.

22. The method according to claim 15, wherein said inspecting step includes a step for inspecting a size and a defect of said predetermined pattern transferred to the semiconductor wafer to thereby determine whether each pattern on the photomask is good or bad.

23. The method according to claim 15, wherein said inspecting step includes a step for comparing a pattern for design data about each pattern to be transferred with the pattern transferred to the semiconductor wafer to thereby determine whether each pattern on the photomask is good or bad.

24. The method according to claim 15, wherein said inspecting step includes a step for comparing a pattern predicted as being transferred based on each pattern on the photomask with the pattern transferred to the semiconductor wafer to thereby determine whether each pattern on the photomask is good or bad.

25. The method according to claim 15, wherein said inspecting step includes a step for comparing patterns transferred to different chip areas of the semiconductor wafer to thereby determine whether each pattern on the photomask is good or bad.

26. The method according to claim 15, wherein the photomask is a photomask having light-shielding patterns each formed of an organic film.

27. The method according to claim 15, wherein the photomask is a photomask having only light-shielding patterns each formed of a metal film.

28. The method according to claim 15, wherein the photomask is a photomask having light-shielding patterns each formed of an organic film and a photomask having only light-shielding patterns each formed of a metal film.
